(19) United States
(12) Patent Application Publication
(10) Pub. No.: US 2024/0326103 A1
(43) Pub. Date: Oct. 3, 2024

(54) APPARATUS FOR REMOVING COATINGS FROM ANGULAR SUBSTRATES

(71) Applicant: OSIRIS INTERNATIONAL GMBH, Singen (DE)

(72) Inventor: Pirmin MUFFLER, Singen (DE)

(21) Appl. No.: 18/577,891

(22) PCT Filed: Jul. 15, 2022
(86) PCT No.: PCT/EP2022/069938

§ 371 Date: Jan. 9, 2024

(30) Foreign Application Priority Data
Jul. 15, 2021 (DE) 10 2021 118 379.0
Jul. 12, 2022 (DE) 10 2022 117 344.5

(51) Int. Cl. B08B 5/02

(52) U.S. Cl. CPC B08B 5/02

(57) ABSTRACT

In an apparatus for removing coatings from angular substrates (2) with a decoating head (3.1, 3.2) and a mobilization device (5), the decoating head (3.1, 3.2) is to be guidable along a substrate longitudinal edge (4.1, 4.2, 4.3, 4.4) of the substrate (2) in a working path.

### TECHNICAL FIELD

The invention relates to an apparatus according to the preamble of claim 1 and to a method for this.

### PRIOR ART

Such apparatuses are already known and in use in many different forms and designs. For example, DE 10 2012 103 330 A1 discloses an apparatus for removing a coating from a substrate.

Substrates, such as wafers or circuit boards, are coated for different applications or processing steps. Usually, this coating takes place over the entire surface of the substrate. For certain applications, however, an edge region of the substrate must be free of the coating. In general, it is very complicated to coat a substrate only in some regions and nevertheless very uniformly. The substrate is therefore usually completely coated and then the coating is removed in a previously defined edge region.

The removal of the coating in the case of round substrates is comparatively simple. Preferably, a nozzle is aimed at the edge region to be removed, at a certain distance, and the coating is then removed by means of solvent applied via the nozzle while the substrate rotates underneath the nozzle. This is possible even when there is a greater requirement for the speed of the decoating.

However, with angular substrates, such as rectangular, square or triangular substrates, it is hardly possible to remove the coating at high speed in this way.

Furthermore, the coating on a substrate can be made up of different layers, which have different solubility or may even be removable only by etching. The removal of the different layers with only one nozzle is not readily feasible.

### OBJECT OF THE INVENTION

The object of the present invention is to overcome the disadvantages of the prior art. In particular, an apparatus is to be provided by means of which the rapid decoating of substrates of any shape is possible. In addition to saving time, the aim is to achieve a decoating quality that is at least as good as before. The standard here is that it should be possible to decoat a substrate in less than one minute and that it should be possible to remove different layers of paint and/or metal on an upper side and/or lower side of the substrate.

### Solution of the Problem

The problem is solved as a result of the features according to claim 1 and claim 10.

The apparatus and method according to the invention for decoating an angular substrate is used to remove so-called photoresist and/or metals from a substrate in the field of photovoltaics or computer chip production. The apparatus and the method are not limited to these two fields, but are designed for them in particular. Decoating of the substrate is here intended to refer to the decoating of both an upper side and/or a lower side of the substrate. The term decoating also includes paint stripping and other terms for the removal of coatings or paint or metal or the like.

So-called decoating heads are used for this, which have corresponding nozzles. The applied photoresist and/or the applied metals, which must be removed in the edge regions of the substrate in order to be able to carry out further processing, is/are usually applied to a carrier plate in liquid form or, in the case of metal, by electroplating or vapor deposition, and form(s) a solid surface after the drying process. The solvent medium and/or etching medium used in the decoating head is generally adapted to the coating to be removed.

The apparatus according to the invention for decoating is required in particular for the decoating of angular substrates and wafers (fiats) that are not entirely round. Such a substrate can have a size of up to 2000 mm×2000 mm, for example. However, other sizes are conceivable. However, round substrates can of course also be used in the present invention. The apparatus has a decoating head and a mobilization device. Substrates that are not round are referred to as angular substrates. Angular substrates are also present for example if a basically square substrate with rounded corner edges is present.

The decoating head has a nozzle through which the solvent medium and/or etching medium is applied to the substrate in a working position. The medium is used to remove the paint or metal on the substrate, i.e. the coating. In particular, the paint and/or metal should be evenly removed from the edge regions of the angular substrate.

Particularly preferably, the solvent medium and/or etching medium should be applied in a straight or jet-like manner. The use of the nozzle results in the advantage that the width of the region to be removed can be determined by how close or how far away from an edge of the substrate the nozzle is guided. Preferably, a region of +/−20 μm, going out from an edge, is to be removed. Furthermore, it is advantageous that removal of the coating is possible without damage to the substrate. Furthermore, it is advantageous that the coating can be completely removed by suitable choice of the solvent medium and/or etching medium and the pressure of the jet.

In typical exemplary embodiments, the nozzle is suitable for discharging the medium jet such that it is guided in a nitrogen jet until it impinges on the coating to be removed. This results in the advantage that the medium jet is very stable and microspatters are removed. The removal of a region of the coating on the substrate is made more precise in this way.

The decoating head can be guided along a substrate longitudinal edge in a working path. In this context, “can be guided” means that the decoating head can be moved back and forth in a first direction.

In the currently existing art, the decoating head is arranged statically and the usually round substrates are held rotating under and/or above the decoating head so that the edge region of the substrate can be decoated. This procedure does not make sense when decoating angular substrates, as only the corner regions would be decoated but not the longitudinal edges of the substrate.

A mobilization device is also provided, the mobilization device and the decoating head being connected to each other in an either-or circuit. Either the decoating head is guided in a working manner or the mobilization device rotates the substrate in such a way that a further substrate longitudinal edge is set into operative connection with the working path of the decoating head.

The mobilization device can also be activated between the back-and-forth movement of the decoating head. Consequently, the first substrate longitudinal edge can be decoated during the forward movement. As soon as the mobilization device has set the further longitudinal substrate edge into an operative connection with the working path of the decoating head, the return movement of the decoating head can be used to decoat the further substrate longitudinal edge. However, depending on the paint and/or metal, it is also possible for the back-and-forth movement of the decoating head to be completed before the mobilization device sets the further longitudinal substrate edge of the substrate into operative connection with the working path of the decoating head.

In order to provide a further increase in efficiency, it is also conceivable for a further working path to be provided with a further decoating head in the apparatus. It is advantageous here that a further increase in efficiency can take place.

It is also advantageous if the decoating head and the further decoating head work simultaneously. In this way, the opposing longitudinal edges of the substrate would be stressed in the same way at the same time, which generally simplifies the stabilization of the substrate and halves the time required to align the substrate.

In addition, it can be provided that the decoating head and the further decoating head can be guided in the same direction or in opposite directions. Here, “in the same direction” means that both decoating heads perform the same movement back and forth in parallel. “In opposite directions” means that the decoating head carries out the forward movement, while the further decoating head carries out the return movement. It is advantageous here that the structure can be arranged in the apparatus in a space-saving manner. If the decoating heads work in opposite directions, there is less of a risk of the supply lines of the two decoating heads obstructing each other in a too-narrow housing of the apparatus.

An extension arm can also be provided on the apparatus. The extension arm is designed in such a way that there is a gas extrusion. The gas extrusion is designed as an air outlet or air outlet nozzle. In the working position, the extension arm slides along the substrate to be decoated on the other side of the associated decoating head. In the case of thin substrates, the substrate can deform if no stabilization were carried out on the other side by the extension arm. The extension arm has the gas extrusion for this purpose. The gas extrusion forms a stabilizing air flow. Ultimately, the gas extrusion is an air outlet which is provided in the extension arm and is designed such that the substrate is exposed to the flow on the other side of the decoating head and is thus stabilized.

“Thin” means that the substrate can have a thickness of less than 1 mm. Of course, the present invention is not limited to this, since substrates having a thickness of several millimeters can also be provided.

Furthermore, it is possible for more than one nozzle to be used in each decoating head. In this way, the working time for decoating the substrate can be advantageously reduced. Furthermore, different solvent media, etching media, water, and/or a gas or gas mixture can also be dispensed through different nozzles, which can, in different ways, dissolve, water-clean, or dry any different layers of a coating that may be on the substrate.

Here the possibility should also be considered of using different nozzles with different solvent medium and/or etching medium for the back-and-forth movements of the decoating heads. For example, it is conceivable to have a first nozzle discharge a first solvent medium/etching medium during the forward movement of a decoating head, while during the return movement another nozzle can then discharge a further solvent medium/etching medium, and a third nozzle could discharge a third solvent medium/etching medium during a further forward movement of the decoating head, etc. Of course, it should also be possible to have all nozzles discharge different solvent/etching media only during the forward movements and/or return movements of the decoating head, even if this does not seem very practicable.

In typical exemplary embodiments, the apparatus further comprises a suction device. This has the advantage that solvent medium and/or etching medium that bounces off the substrate does not enter the environment or the process environment, but can be suctioned away, possibly treated, and, under some circumstances, recycled. A further advantage of the suction device is that the coating removed from the substrate can also be suctioned off and does not enter the process environment. For this purpose, the suction device is preferably provided with a hood. The hood therefore serves as an additional protective device against the spraying around of solvent medium and/or etching medium and/or dissolved coating.

In addition, sensor monitoring is provided. The sensor monitoring in the quality assurance of the working process.

In addition, a method according to the invention for removing coatings from angular substrates is claimed. The decoating head and a mobilization device are also used there, wherein the decoating head is guided along a substrate longitudinal edge of the substrate in a working path, and the mobilization device subsequently brings a further longitudinal substrate edge of the substrate into operative connection with the working path of the decoating head. For this purpose, the decoating head and the mobilization device have an either-or circuit. This means that either the decoating head becomes active or the mobilization device becomes active. It is not ruled out that the decoating head performs the decoating during a forward movement. Subsequently, the mobilization device can bring a further longitudinal substrate edge of the substrate into the working path of the decoating head by rotating the substrate by 90 degrees. Then the further substrate longitudinal edge is in turn decoated during the return movement. In this way, for example a further increase in efficiency can be achieved.

A further decoating head can also be used in the method according to the invention, which simultaneously processes and decoats a further substrate longitudinal edge with a further working path. It is advantageous here if the decoating head and the further decoating head work simultaneously. The decoating head moves on its working path and the further decoating head moves on its own further working path.

Furthermore, the decoating head and the further decoating head are guided either in the same direction or in opposite directions. Here, “in the same direction” means that the decoating head and the further decoating head are moved parallel next to one another in one direction. “In opposite directions” means here that the decoating head carries out, for example, the forward movement, while the further decoating head simultaneously carries out the return movement. In the sense of the invention, “at the same time” means that small time delays are to be included. Time delays in almost imperceptible time windows are to be regarded as simultaneous or synchronous. The same also applies if the two decoating heads run at different speeds and either the start or end point of the respective working path is simultaneously reached.

It should also be possible to carry out a decoating of the substrate or of the substrate edge both on an upper side and on a lower side of the substrate, either successively or simultaneously.

During the decoating process or the working process or the working position, on the other side of the substrate an extension arm moves which is either materially connected to the corresponding associated decoating head or, as part of the apparatus, moves independently of the decoating head on the other side of the substrate in the working position and, at the level of the decoating head, always directs a flow of a gas or gas mixture onto the part of the substrate longitudinal edge which is currently being processed by the decoating head on the other side of the substrate. This is advantageous since in this way the region of the substrate or of the substrate longitudinal edge which is currently being decoated is stabilized.

In the present case, the use of one or two decoating heads is intended and described. However, the invention is also intended to include the provision of more than two decoating heads. Thus, for example, three or four decoating heads can also be provided, or in substrates with more than four side longitudinal edges more than four decoating heads can also be provided. These would then only have to be switched in such a way that they do not interfere with each other in their back-and-forth movement.

Furthermore, the present invention is intended to enable an edge decoating specifically of quadrangular substrates with ABF coating (Ajinomoto Build-up Film) or other resinous coatings. For this purpose, the quadrangular substrates are supplied with an ABF coating, for example. They are covered adhesively with a plastic film (PET in the case of ABF) in such a way that the film covers almost the entire coating. Outside the film, an edge of a few millimeters usually remains free and is not covered with the film. By applying the film to the region coated with, for example, ABF, some of the ABF is pressed outwards and swells out from under the film. This excess coating material must be removed.

The following process steps are used to remove this residual coating from the edge:
Soaking the coating by applying a solvent (in the case of ABF, for example MEK=methyl ethyl ketone: butanone) with low pressure.
After a soaking phase, the dissolved but slimy-greasy coating material can be removed by a high-pressure jet from a fan nozzle, so that only the coating remains under the film.

In this process, low-pressure and high-pressure nozzles are combined in one nozzle head. In the first step, only the low-pressure nozzles are switched on and the solvent is applied for the dissolving. After a waiting time of about 15 seconds (in the case of ABF), the coating is then removed in the second pass using the high-pressure fan nozzles. The exposure time can vary depending on the coating material and layer thickness. With this process, it is also possible for the substrate to be simultaneously decoated at the top and bottom.

### DESCRIPTION OF THE DRAWINGS

Further advantages, features, and details of the invention result from the following description of preferred exemplary embodiments and on the basis of the drawings, in which:

FIG. 1 shows a schematic plan view of an apparatus for decoating an angular substrate; and

FIG. 2 shows a schematic side view of the apparatus according to FIG. 1.

### EXEMPLARY EMBODIMENT

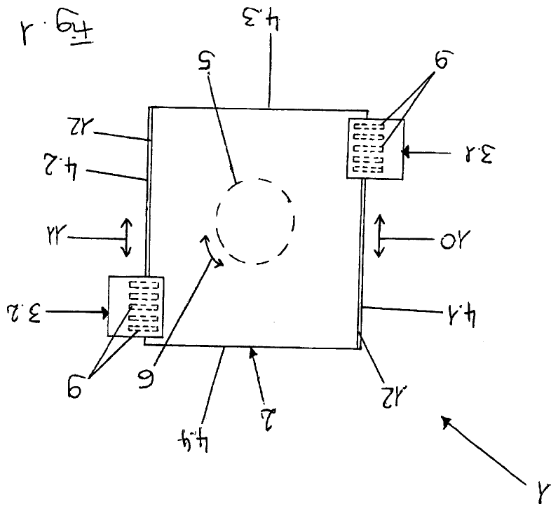

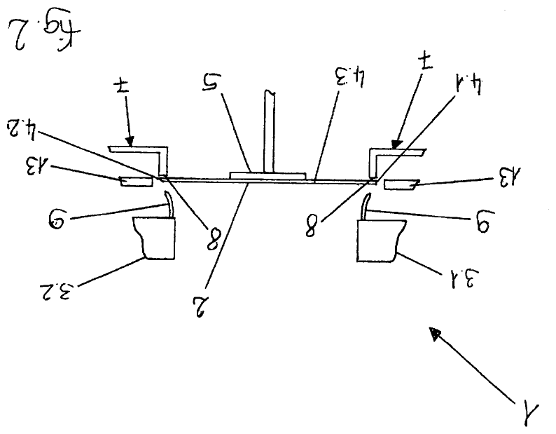

FIGS. 1 and 2 show an apparatus 1 for decoating angular substrates 2. The decoating comprises the removal of a coating, in particular photoresist and/or metals from a surface of the substrate 2, and in the present case in particular from edge regions 12 of the substrate 2.

Examples of possible substrates are square wafers, rectangular wafers, polygonal wafers, thin-film plates, circuit boards, or the like.

In the present case, the apparatus 1 has two decoating heads 3.1 and 3.2 which can be guided along a substrate longitudinal edge 4.1 or 4.2 of the substrate 2 in a working path along the arrows 10 and 11. That is, the decoating heads 3.1 and 3.2 can be moved in the X and Y direction along the arrows 10 and 11. However, it should also be possible to move the decoating heads 3.1 and 3.2 in the Z direction. Thus, a distance between the decoating head 3.1 or 3.2 and the surface of the substrate 2 can be set, but a distance can also be set between the decoating head 3.1 or 3.2 and the respective substrate longitudinal edge 4.1 or 4.2. The decoating heads 3.1 and 3.2 can be adjusted and moved by means of an adjusting device (not shown in detail).

The apparatus 1 also has a mobilization device 5 for holding, positioning and/or aligning the substrate 2. The mobilization device 5 is shown in dashed lines in FIG. 1. In the present case, it allows a rotation of the substrate 2 by 90 degrees in the direction of arrow 6, whereby a further substrate longitudinal edge 4.3 or 4.4 of the substrate 2 can move into operative connection with the working path of the decoating head 3.1 or 3.2.

The decoating head 3.1 or 3.2 and the mobilization device 5 have an either-or circuit (not shown in detail). This circuit brings it about that either the decoating heads 3.1 and 3.2 are guided along the substrate longitudinal edge 4.1 or 4.2 or 4.3 or 4.4 in their working path or the mobilization device 5 rotates the substrate 2. As a result, the individual elements do not interfere with each other.

Furthermore, the two decoating heads 3.1 and 3.2 act in preferably opposite directions. However, the movement of the two decoating heads 3.1 and 3.2 in the same direction is also intended to be included in the sense of the invention. However, this is only possible if the substrate 2 is sufficiently large that sufficient space remains for the corresponding decoating head 3.1 or 3.2 along the respective substrate longitudinal edge.

The apparatus 1 also has an extension arm 7 which, in the working position, is arranged in each case on a side of the substrate 2 opposite the decoating head 3.1 or 3.2. The extension arm 7 is provided with a gas extrusion 8 for the substrate 2. Via this arm, a stabilizing air flow is applied in the direction of the substrate 2. Since the substrate 2 can generally be made very thin (down to less than 1 mm), it could bulge or sag downwards during the course of the processing if the substrate has a large surface. The region to be decoated could thus have irregularities. In order to prevent this, the stabilization stream is applied in the direction of the substrate 2 via the gas extrusion 8. Consequently, the substrate 2 on the other side of the decoating head 3.1 or 3.2 is exposed to the stabilizing air flow via the gas extrusion 8 and is thus stabilized and drawn flat so that the substrate 2 can be uniformly decoated.

For decoating, each decoating head 3.1 and 3.2 has more than one nozzle 9, preferably five to six nozzles 9.

Furthermore, the apparatus 1 has a sensor monitoring system (not shown in detail), preferably for quality assurance.

With reference to FIGS. 1 and 2, the operation of the apparatus according to the invention is explained as follows:

The substrate 2 from which the coating is to be removed is placed on the mobilization device 5 and held by suction cups (not shown in more detail). Two decoating heads 3.1 and 3.2 are positioned at the two opposite substrate longitudinal edges 4.1 and 4.2 at a previously determined distance from the substrate longitudinal edge 4.1 or 4.2, in such a way that they are arranged on the one hand diagonally to one another. On the other hand, the nozzles 9 of the decoating heads 3.1 and 3.2 have to be arranged at a predetermined distance from the surface of the substrate 2 and in particular from the region to be decoated of the substrate 2.

At the same time, the extension arms 7 with the gas extrusion 8 are positioned a short distance below the substrate or on the sides of the substrate 2 opposite the decoating heads 3.1 or 3.2. This is done in such a way that the stabilizing air flow from the gas extrusion 8 can flow directly onto the region to be stabilized on the opposite side of the edge region 12 of the substrate 2. The air flows very quickly through the small gap between the gas extrusion 8 and the substrate 2. The static pressure between the two elements decreases. A lower pressure thus acts on the lower side of the substrate 2 than on the upper side. The substrate 2 is therefore pressed downwards by the greater ambient pressure on the upper side.

Once the substrate 2 has been positioned on the mobilization device 5 and the decoating heads 3.1 and 3.2 have been positioned at the substrate longitudinal edges 4.1 and 4.2, the decoating heads 3.1 and 3.2 are moved along the substrate longitudinal edges 4.1 and 4.2 in their working path, in the present case in opposite directions, i.e. in the direction of the distal end, shown in relation to FIG. 1, of the respective substrate longitudinal edge 4.1 or 4.2.

While the decoating heads 3.1 and 3.2 are guided along the substrate longitudinal edges 4.1 and 4.2 in their working path, at the same time the extension arms 7 together with the gas extrusion 8 are also guided uniformly underneath the substrate 2 in order to direct flow onto the substrate 2 so that it can be kept uniformly flat during the decoating process. If the substrate 2 were skewed or curved, the coating could not be removed uniformly or in the desired region. A substrate that curves would also be problematic because in some circumstances too much or too little material would be removed. The leveling of the substrate 2 thus takes place at the same time as the travel of the decoating heads 3.1 and 3.2 along the substrate longitudinal edges 4.1 and 4.2, and consequently as the decoating.

Furthermore, while the decoating heads 3.1 and 3.2 are moved along the substrate longitudinal edges 4.1 and 4.2 in the working path, one or more solvent media and/or etching media are sprayed via the nozzles 9, depending on the structure of a coating on the substrate surface. For this purpose, the nozzles 9 are connected to a media pump (not shown in detail) and a solvent or etching medium reservoir (not shown in detail). The media pump is preferably suitable for discharging the solvent medium and/or etching medium under (low) pressure. At the same time, the solvent medium and/or etching medium is preferably applied in a straight or also jet-like manner. For this purpose, the nozzles 9 are preferably connected to a compressed air source or nitrogen source (not shown in detail). In order to be able to discharge the solvent medium and/or etching medium and the compressed air nitrogen jet, the nozzles 9 can have two dispensing tubes (not shown in detail) which are guided in one another. Preferably, the solvent medium and/or etching medium is discharged from an inner tube in a straight or jet-like manner and under pressure. The compressed air jet or nitrogen jet is then discharged from the outer tube. In this way, the coating is then dissolved and removed along the substrate longitudinal edges 4.1 and 4.2.

Suitable solvents, etching media, or small particles that have an abrasive effect can be used as the solvent medium.

The coating removed by the solvent medium and/or etching medium, and/or also the solvent medium and/or etching medium itself, must be removed from the substrate 2 in such a way that the substrate is not damaged. For this purpose, a suction device 13 with a hood (not shown in detail) is provided, which is connected via a line (not shown in detail) to a vacuum source (not shown in detail). The hood acts as an additional protective device against solvent medium and/or etching medium being sprayed around.

When the decoating heads 3.1 and 3.2 have each reached the distal end of the substrate longitudinal edge 4.1 or 4.2 and have completed the decoating process for these substrate longitudinal edges 4.1 and 4.2, the decoating heads 3.1 and 3.2 are moved back to their starting position in the working path. The mobilization device 5 then rotates the substrate 2 by 90 degrees and the further substrate longitudinal edges 4.3 and 4.4 of the substrate 2 are brought into operative connection with a further working path of a further decoating head, and the processes described above are repeated. As a result of the either-or circuit, either the decoating heads 3.1 and 3.2 or the mobilization device 5 are in action. These steps listed above are repeated until all desired edges and/or sides of the substrate 2 have been processed and decoated completely or at least to the extent desired.

Although only one preferred embodiment of the invention has been described and shown, it is obvious that a person skilled in the art can add numerous modifications without departing from the essence and scope of the invention.

List of reference signs

| | |
|---|---|
| 1 | Apparatus |
| 2 | Substrate |
| 3 | Decoating head |
| 4 | Substrate longitudinal edge |
| 5 | Mobilization device |
| 6 | Arrow |
| 7 | Extension arm |
| 8 | Gas extrusion |
| 9 | Nozzle |
| 10 | Arrow |
| 11 | Arrow |
| 12 | Edge region |
| 13 | Suction device |
| 14 | |
| 15 | |
| 16 | |
| 17 | |
| 18 | |
| 19 | |
| 20 | |
| 21 | |
| 22 | |
| 23 | |
| 24 | |
| 25 | |
| 26 | |
| 27 | |
| 28 | |
| 29 | |
| 30 | |
| 31 | |
| 32 | |
| 33 | |
| 34 | |
| 35 | |
| 36 | |
| 37 | |
| 38 | |
| 39 | |
| 40 | |
| 41 | |
| 42 | |
| 43 | |
| 44 | |
| 45 | |
| 46 | |
| 47 | |
| 48 | |
| 49 | |
| 50 | |
| 51 | |
| 52 | |
| 53 | |
| 54 | |
| 55 | |
| 56 | |
| 57 | |
| 58 | |
| 59 | |
| 60 | |
| 61 | |
| 62 | |
| 63 | |
| 64 | |
| 65 | |
| 66 | |

1. An apparatus for decoating an angular substrate, comprising a decoating head and a mobilization device, wherein the decoating head is configured to be guided along a substrate longitudinal edge of the angular substrate in a working path.

2. The apparatus according to claim 1, wherein the mobilization device is configured to set a further longitudinal substrate edge of the angular substrate into an operative connection with the working path of the decoating head, wherein the decoating head and the mobilization device comprise an either-or circuit.

3. The apparatus according to claim 1, wherein a further working path is provided with a further decoating head.

4. The apparatus according to claim 3, wherein the decoating head and the further decoating head are configured to be guided in the same direction or in opposite directions.

5. The apparatus according to claim 1 further comprising an extension arm, and the extension arm comprises a gas extrusion.

6. The apparatus according to claim 5, wherein the extension arm in a working position is arranged on a side of the angular substrate opposite the decoating head.

7. The apparatus according to claim 5, wherein the extension arm has the gas extrusion for a stabilizing air flow, and wherein the gas extrusion is set up to direct flow onto the angular substrate on the other side of the decoating head.

8. The apparatus according to claim 1, wherein said decoating head has more than one nozzle.

9. The apparatus according to claim 1, wherein there is a sensor monitoring.

10. A method for decoating an angular substrate with a decoating head and a mobilization device, wherein the decoating head is mobilized along a substrate longitudinal edge of the angular substrate in a working path.

11. The method according to claim 10, wherein the mobilization device brings a further substrate longitudinal edge of the angular substrate into operative connection with the working path of the decoating head, wherein the decoating head and the mobilization device are connected via an either-or circuit.

12. The method according to claim 10, wherein a further substrate longitudinal edge of the angular substrate is brought into operative connection with a further working path of a further decoating head.

13. The method according to claim 12, wherein the decoating head and the further decoating head are guided in the same direction or in opposite directions.

14. The method according to claim 10, wherein a stabilizing air flow of a gas extrusion of an extension arm flows onto and stabilizes the substrate on the other side of the decoating head.

15. The apparatus according to claim 1, wherein there is more than one said decoating head, and each said decoating head has more than one nozzle.

16. The apparatus according to claim 15, wherein there is a sensor monitoring.

17. The apparatus according to claim 8, wherein there is a sensor monitoring.
